(19) United States
(12) Patent Application Publication
(10) Pub. No.: US 2026/0090319 A1
(43) Pub. Date: Mar. 26, 2026

(54) SUBSTRATE PROCESSING APPARATUS AND SUBSTRATE PROCESSING METHOD

(71) Applicant: SAMSUNG ELECTRONICS O., LTD., Suwon-si (KR)

(72) Inventors: Jisoo LEE, Suwon-si (KR); Sanagjine PARK, Suwon-si (KR)

(73) Assignee: SAMSUNG ELECTRONICS CO.,LTD., Suwon-si (KR)

(21) Appl. No.: 19/075,057

(22) Filed: Mar. 10, 2025

(30) Foreign Application Priority Data
Sep. 26, 2024 (KR) 10-2024-0130724

(51) Int. Cl. H01L 21/67; H01L 21/677

(52) U.S. Cl. CPC H10P 72/0462; H10P 72/0426; H10P 72/0441; H10P 72/0602; H10P 72/3411

(57) ABSTRACT

A substrate processing apparatus includes a first chamber, a substrate loader under a first pressure and including a load port configured to load a substrate, a processing chamber inside the first chamber and including a processing bath in which a processing liquid for processing the substrate is provided and a bath cover configured to cover the processing bath, a processing liquid supplier configured to supply the processing liquid to the processing chamber, a first gas supply device configured to cause an internal pressure of the first chamber to be at a second pressure higher than the first pressure by supplying gas into the first chamber, and a second gas supply device configured to cause an internal pressure of the processing chamber to be at a third pressure higher than the first pressure by supplying gas into the processing chamber.

### CROSS-REFERENCE TO RELATED APPLICATION

This application is based on and claims priority to Korean Patent Application No. 10-2024-0130724, filed on Sep. 26, 2024, in the Korean Intellectual Property Office, the disclosure of which is incorporated by reference herein in its entirety.

### BACKGROUND

The present disclosure relates to a substrate processing apparatus and a substrate processing method.

Manufacturing a semiconductor device may involve performing a series of processes such as etching, ashing, ion implantation, thin film deposition, etc. Various processing liquids and gases are used in each of the processes, and particles and process by-products may be generated in those processes. In particular, a cleaning process to remove thin films, particles, and process by-products on a substrate, or an etching process to remove target materials may be performed with the processing liquid.

The substrate processing method using the processing liquid may be classified into a batch processing method that processes a plurality of substrates together and a single wafer processing method that processes the substrates one by one. In particular, the batch processing method may involve performing collectively immersing a plurality of substrates in a tank including processing liquid, and in doing so, methods are being studied to quickly etch the target material to increase the etch rate per unit time and ensure the selectivity.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Example embodiments provide a substrate processing apparatus and a substrate processing method with increased processing efficiency.

Example embodiments also provide a substrate processing apparatus and a substrate processing method with an improved etch rate per unit time and selectivity.

Example embodiments further provide a substrate processing apparatus and a substrate processing method capable of improving the quality of a semiconductor device.

According to an aspect of an example embodiment, a substrate processing apparatus may include a first chamber, a substrate loader under a first pressure and including a load port configured to load a substrate, a processing chamber inside the first chamber and including a processing bath in which a processing liquid for processing the substrate is provided and a bath cover configured to cover the processing bath, a processing liquid supplier configured to supply the processing liquid to the processing chamber, a first gas supply device configured to cause an internal pressure of the first chamber to be at a second pressure higher than the first pressure by supplying gas into the first chamber, and a second gas supply device configured to cause an internal pressure of the processing chamber to be at a third pressure higher than the first pressure by supplying gas into the processing chamber.

According to an aspect of an example embodiment, a substrate processing method may include causing an internal pressure of a first chamber to be higher than an atmospheric pressure by supplying gas through a first gas supply device connected to the first chamber, moving a substrate into the first chamber, moving the substrate into a processing chamber in the first chamber, where the processing chamber contains a processing liquid for processing the substrate, sealing the processing chamber by covering the processing chamber with a bath cover, and causing an internal pressure of the processing chamber to be substantially equal to the internal pressure of the first chamber by supplying gas through a second gas supply device connected to the processing chamber.

According to an aspect of an example embodiment, a substrate processing apparatus may include a first chamber under an internal pressure higher than an atmospheric pressure, a substrate loader including a load port configured to receive a plurality of substrates and a buffer chamber of which an internal pressure is adjustable, a plurality of processing chambers respectively configured to accommodate the plurality of substrates, each of the plurality of processing chambers containing a processing liquid, a processing liquid supplier configured to supply the processing liquid to each of the plurality of processing chambers, a transfer device configured to transfer a batch type container accommodating the plurality of substrates, a first gas supply device configured to supply gas into the first chamber, a second gas supply device configured to supply gas into each of the plurality of processing chambers, and a third gas supply device configured to supply gas to the buffer chamber, where each of the plurality of processing chambers includes a processing bath including an inner wall contacting the processing liquid, and an outer wall at least partially surrounding the inner wall, where at least one side of the processing bath is open, a bath cover configured to be coupled to the at least one open side of the processing bath, a sealing member between the processing bath and the bath cover and configured to seal an inside of a respective processing chamber, and a bath heater in the outer wall of the processing bath and configured to control a temperature of the processing liquid.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a substrate processing apparatus according to one or more embodiments;

FIG. 2 is a block diagram of components for controlling a substrate processing apparatus according to one or more embodiments;

FIGS. 3 and 4 are flowcharts of a transfer process of a substrate in a substrate processing apparatus according to one or more embodiments;

FIG. 5 is a diagram illustrating a partial configuration of a substrate processing apparatus according to one or more embodiments;

FIG. 6 is a diagram illustrating a processing chamber in an open state according to one or more embodiments;

FIG. 7 is a diagram illustrating a processing chamber in a sealed state according to one or more embodiments;

FIGS. 8 and 9 are diagrams illustrating a processing chamber according to one or more embodiments;

FIG. 10 is a flowchart of a substrate processing method according to one or more embodiments;

FIGS. 11 and 12 are flowcharts of a method for adjusting internal pressure of a processing chamber according to one or more embodiments;

FIG. 13 is a graph illustrating a relationship between a temperature of processing liquid in a processing chamber and an etch rate according to one or more embodiments; and

FIG. 14 is a graph illustrating a relationship between a concentration of a processing liquid and selectivity according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A substrate processing apparatus and a substrate processing method according to one or more embodiments of the present disclosure will be described in detail with reference to the drawings.

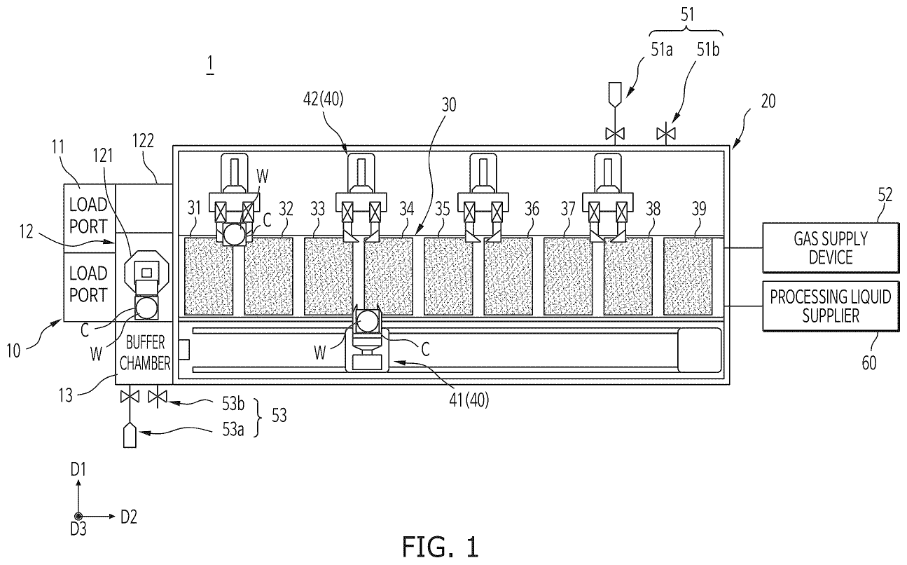

FIG. 1 is a diagram illustrating a substrate processing apparatus according to one or more embodiments.

Referring to FIG. 1, a substrate processing apparatus 1 may include a substrate loader 10, a chamber 20, a processing chamber 30, a transfer device 40, a plurality of gas supply devices 51, 52, 53, and a processing liquid supplier 60. The substrate processing apparatus 1 may be a batch type processing apparatus that processes a plurality of substrates W, but may also be a single wafer type. In addition, part of the substrate processing apparatus 1 may be a batch type, and the rest may be a single wafer type. The substrate processing apparatus 1 may be used in at least one of wet etching, cleaning, and drying processes of the substrate W.

The substrate loader 10 may load the substrate W into the substrate processing apparatus 1. The substrate loader 10 may extend in a first direction D1. The substrate W may be transferred to the chamber 20 through the substrate loader 10. Atmospheric pressure may be formed outside the substrate loader 10. A first pressure or atmospheric pressure may be formed on a portion of the substrate loader 10 connected to the outside. That is, a load port 11 and a transfer module 12, which will be described below, may be disposed under atmospheric pressure.

The substrate loader 10 may include the load port 11, the transfer module 12, and a buffer chamber 13. A carrier may be seated in the load port 11. The carrier may store a substrate. The substrate W may be a semiconductor wafer. The carrier may include a Front Opening Unified Pod (FOUP), a Front Opening Shipping Box (FOSB), a run box, etc.

The load port 11 may unload the substrate W from the carrier and load the substrate W into the transfer module 12. The load port 11 may serve as an interface between the substrate loader 10 and the carrier. A plurality of load ports 11 may be provided.

Although two load ports 11 are illustrated, the number of load ports 11 may be increased or decreased depending on various conditions. For example, the plurality of load ports 11 may be arranged side by side in the first direction D1.

The substrate W unloaded from the carrier may be loaded into the container C. For example, the container C may have a cylindrical shape with an open part. A plurality of substrates W may be accommodated in the container C. The container C may include a plurality of slots for supporting and receiving a plurality of substrates W. The container C carrying the substrate W may be loaded into the transfer module 12 through the load port 11. However, embodiments are not limited thereto, and the substrate W may be loaded without being accommodated in the container C.

A transfer robot 121 and a posture changing device 122 may be disposed in the transfer module 12. The transfer robot 121 may transfer the substrate W loaded into the transfer module 12 or the container C accommodating the substrate W. The posture changing device 122 may change the posture of the loaded container C. For example, the posture changing device 122 may rotate an open portion of the container C so that it faces upward.

The transfer module 12 may be connected to the buffer chamber 13. The substrate W or the container C on which the substrate W is mounted may be transferred from the transfer module 12 to the buffer chamber 13. In order to transfer the container C from the transfer module 12 to the buffer chamber 13, it may be necessary that the internal pressure of the transfer module 12 and the internal pressure of the buffer chamber 13 are substantially the same.

The buffer chamber 13 may be disposed between the transfer module 12 and the chamber 20. The substrate W or the container C accommodating the substrate W may be loaded into the buffer chamber 13. The buffer chamber 13 may transfer the substrate W or the container C accommodating the substrate W into the chamber 20. The chamber 20 may be connected to the buffer chamber 13. The chamber 20 may receive the substrate W or the container C from the buffer chamber 13.

The internal pressure of the buffer chamber 13 may be adjusted. The internal pressure of the buffer chamber 13 may be adjusted between the first pressure and a second pressure higher than the first pressure. For example, the first pressure may be atmospheric pressure, and the second pressure may be higher than the atmospheric pressure. The atmospheric pressure is not limited to a specific predetermined pressure value (e.g., 1.013 bar), and may include a case where a separate component for adjusting pressure is not provided. That is, the first pressure may vary depending on various conditions such as altitude, temperature, etc. at which the substrate processing apparatus 1 is disposed.

The internal pressure of the buffer chamber 13 may be adjusted to be substantially equal to the external pressure of the substrate loader 10 or the pressure state in which the transfer module 12 is placed, so that the substrate W or the container C may be received from the transfer module 12. In order to transfer the substrate W or the container C from the buffer chamber 13 to the chamber 20, the internal pressure of the buffer chamber 13 may be adjusted to be substantially equal to the internal pressure of the chamber 20.

The internal pressure of the chamber 20 may be adjusted to be higher than the first pressure. The internal pressure of the chamber 20 may be adjusted to the second pressure. For example, the internal pressure of the chamber 20 may be approximately atmospheric pressure or more and 10 bar or less.

The transfer device 40 for transferring the substrate W or the container C accommodating the substrate W may be provided inside the chamber 20. The transfer device 40 may transfer the substrate W or the container C accommodating the substrate W to the processing chamber 30 or from the processing chamber 30 to the buffer chamber 13.

The transfer device 40 may include a first transfer device 41 and a second transfer device 42. The first transfer device 41 may receive the substrate W or the container C from the buffer chamber 13 or may unload the substrate W or the container C into the buffer chamber 13. For example, the first transfer device 41 may move along a second direction D2, but embodiments are not limited thereto. The second transfer device 42 may transfer the substrate W or the container C in the second direction D2. The second transfer device 42 may transfer the substrate W processed in the processing chamber 30 or the container C to another processing chamber 30. For example, the second transfer device 42 may transfer the substrate W or the container C from the processing chamber 30 where the wet etching process is performed to the processing chamber 30 for rinsing. A plurality of second transfer devices 42 may be provided, and each of the second transfer devices 42 may transfer the substrate W or the container C between adjacent processing chambers 30.

A plurality of processing chambers 30 may be disposed inside the chamber 20. In one or more embodiments, and for example shown in FIG. 1, nine processing chambers 30 may be provided. The plurality of processing chambers 30 may include first to ninth processing chambers 31 to 39. The plurality of processing chambers 30 may be disposed along the second direction D2. The plurality of processing chambers 30 may sequentially perform semiconductor processes on a plurality of substrates W. For example, the processes may include a wet etching process in which the substrate W is immersed in an etchant in the first processing chamber 31, a rinsing process of rinsing the etchant in the second processing chamber 32, and a drying process of drying the rinse liquid in the third processing chamber 33. In one or more embodiments, the processes may include the wet etching process performed in the first to third processing chambers 31, 32, and 33, the rinsing process performed in the fourth to sixth processing chambers 34, 35, and 36, and the drying process in the seventh to ninth processing chambers 37, 38, and 39. Although nine processing chambers 31-39 are shown, embodiments are not limited thereto, and fewer or more than none processing chambers may be implemented.

The plurality of gas supply devices may include a first gas supply device 51, a second gas supply device 52, and a third gas supply device 53.

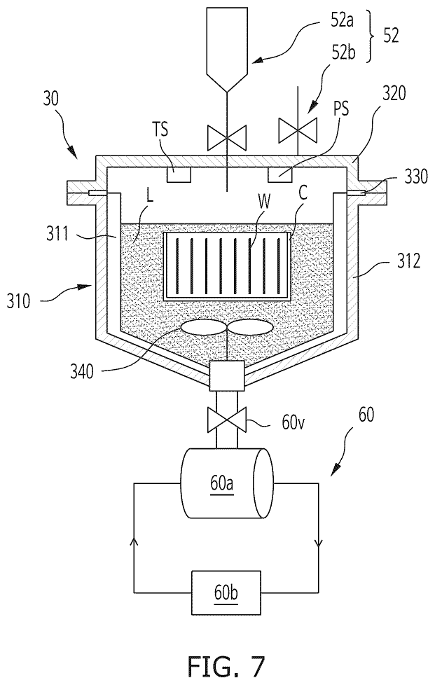

Each of the first gas supply device 51, the second gas supply device 52, and the third gas supply device 53 may include a first gas supplier 51a, a second gas supplier 52a (see FIG. 7), and a third gas supplier 53a. The first gas supplier 51a may supply gas to the chamber 20. The first gas supplier 51a may supply gas to the chamber 20 to adjust the internal pressure of the chamber 20. The second gas supplier 52a may supply gas to the processing chamber 30. The second gas supplier 52a may supply gas to the processing chamber 30 to adjust the internal pressure of the processing chamber 30. The third gas supplier 53a may supply gas to the buffer chamber 13. The third gas supplier 53a may supply gas to the buffer chamber 13 to adjust the internal pressure of the buffer chamber 13. In one or more embodiments, a single gas supply device may be configured to supply gas to each of the buffer chamber 13, the chamber 20, and the processing chamber 30. The plurality of gas supply devices may supply gas having low reactivity such as nitrogen (N₂), argon (Ar), neon (Ne), helium (He), and carbon dioxide (CO₂).

Each of the first gas supply device 51, the second gas supply device 52, and the third gas supply device 53 may include a first pressure adjuster 51b, a second pressure adjuster 52b (see FIG. 7), and a third pressure adjuster 53b. For example, the pressure adjusters may correspond to various devices that are configured to adjust the pressure inside the chambers 13, 20 and 30. One or more examples of the pressure adjusters may include a valve, a pump, etc. that are configured to discharge gas in the chambers. The valves, pumps, etc., may be electronically controlled to discharge gas in response to detection of excess pressure, in response to a control signal for adjusting the pressure, etc. The pressure adjusters may be configured with various settings for adjusting the pressure inside the chambers to various predetermined pressure states as described herein, by discharging gas that was supplied by a corresponding gas supplier. The pressure adjusters may be connected to the controller in order to implement such settings. The pressure adjusters may be controlled by a controller in response to user input or in response to various detected states within the chambers. The first pressure adjuster 51b may be configured to control the first gas supplier 51a to discharge the gas inside the chamber 20. If an excessive amount of gas is supplied inside the chamber 20, resulting in the pressure inside the chamber 20 being higher than the target pressure, or if it is necessary to reduce the internal pressure of the chamber 20, the first pressure adjuster 51b may discharge some gas to control the internal pressure of the chamber 20. The second pressure adjuster 52b may discharge the gas inside the processing chamber 30. If an excessive amount of gas is supplied inside the processing chamber 30, resulting in the pressure inside the processing chamber 30 being higher than the target pressure, or if it is necessary to reduce the internal pressure of the processing chamber 30, the second pressure adjuster 52b may discharge some gas to control the internal pressure of the processing chamber 30. The third pressure adjuster 53b may discharge gas inside the buffer chamber 13. If an excessive amount of gas is supplied inside the buffer chamber 13, resulting in the pressure inside the buffer chamber 13 being higher than the target pressure, or if it is necessary to reduce the internal pressure of the buffer chamber 13, the third pressure adjuster 53b may discharge some gas to control the internal pressure of the buffer chamber 13.

The processing liquid supplier 60 may supply the processing liquid into the processing chamber 30. The processing liquid supplier 60 may supply different processing liquids according to the functions of the processing chamber 30. For example, the processing liquid supplier 60 may supply tetramethylammonium hydroxide (TMAH) to the first processing chamber 31 where the wet etching process is performed, supply deionized water to the second processing chamber 32 where the rinsing process is performed, and supply isopropyl alcohol (IPA) to the third processing chamber 33 where the drying process is performed. In one or more embodiments, the processing liquid may be supplied from one processing liquid supplier to a plurality of processing chambers where the same process is performed, and the processing liquid may be supplied from a different processing liquid supplier to the processing chamber where a different process is performed.

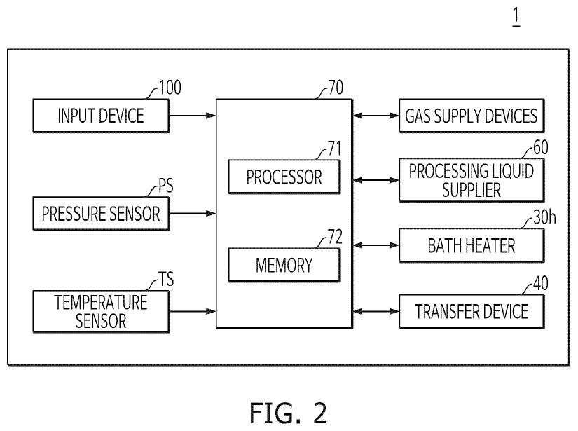

FIG. 2 is a block diagram of components for controlling a substrate processing apparatus according to one or more embodiments.

Referring to FIG. 2, the substrate processing apparatus 1 may include an input device 100, a temperature sensor TS, a pressure sensor PS, a controller 70, the plurality of gas supply devices, the processing liquid supplier 60, a bath heater 30h, and the transfer device 40.

The input device 100 may receive a control command from a user. That is, the input device 100 may receive a command for controlling the components of the substrate processing apparatus 1. For example, the processing atmosphere of the substrate may be set through the input device 100. Specifically, an internal pressure value of the processing chamber 30 may be set through the input device 100.

The temperature sensor TS may measure at least one of the internal temperature of the processing chamber 30 and the temperature of the processing liquid. The temperature sensor TS may be disposed inside the processing chamber 30. Temperature data measured from the temperature sensor TS may be transmitted to the controller 70. The controller 70 may adjust the pressure inside the processing chamber 30 based on the temperature data measured by the temperature sensor TS. For example, if the temperature measured by the temperature sensor TS rises, the controller 70 may control the plurality of gas supply devices to reduce the amount of gas to supply to reach a target pressure value.

The pressure sensor PS may measure an internal pressure of each of the buffer chamber 13, the chamber 20, and the processing chamber 30. The pressure sensor PS may be disposed in each of the buffer chamber 13, the chamber 20, and the processing chamber 30. The pressure data measured from the pressure sensor PS may be transmitted to the controller 70. The controller 70 may adjust the pressure inside the processing chamber 30 based on the pressure data measured by the pressure sensor PS. For example, if the pressure measured by the pressure sensor PS is higher than the target pressure value, the controller 70 may control the plurality of gas supply devices to discharge some of the gas inside the processing chamber 30.

The controller 70 may control the plurality of gas supply devices or the bath heater 30h based on at least one of the input data received from the input device 100, the temperature data measured from the temperature sensor TS, and the pressure data measured from the pressure sensor PS.

The controller 70 may control the processing liquid supplier 60 based on at least one of the input data received from the input device 100 and the temperature data measured from the temperature sensor TS.

The controller 70 may control the transfer device 40 based on at least one of the input data received from the input device 100 and the pressure data measured from the pressure sensor PS.

When the controller 70 controls the component of the substrate processing apparatus, it may include all of, a combination of, or at least one of directly transmitting a control signal to the component, transmitting a control signal to a separate driving device that drives the component, and transmitting a control signal to another intermediate component necessary to control the component.

The controller 70 may include a memory 72 that stores a program and various types of data for executing the operations already described above or will be described below, and a processor 71 that processes data by executing the program stored in the memory 72.

The memory 72 may include at least one of a volatile memory such as a static random access memory (SRAM), a dynamic random access memory (DRAM), etc., and a non-volatile memory such as a flash memory, a read only memory (ROM), an erasable programmable read only memory (EPROM), an electrically erasable programmable read only memory (EPROM), etc.

The non-volatile memory may operate as an auxiliary memory device of the volatile memory, and may retain stored data even if the power of the substrate processing apparatus is interrupted. For example, the non-volatile memory may store a control program and control data for controlling the operation of the substrate processing apparatus.

Unlike the non-volatile memories, the volatile memories may lose stored data when power of the substrate processing apparatus is interrupted. The volatile memory may load the control program and control data from the non-volatile memory and temporarily store the control program and the control data, temporarily store an input setting value or control command, or temporarily store a control signal, etc. output from the processor 71.

The processor 71 may process data or output a control signal according to the program stored in the memory 72. For example, the processor 71 may process data or output a control signal according to a program that is stored in the memory 72 and that includes instructions for executing the operation of the substrate processing apparatus or the substrate processing method.

The processor 71 and the memory 72 may be provided in a single configuration or may be provided in a plurality of configurations according to their capacities. In addition, the processor 71 and the memory 72 may be physically separated or may be provided as a single chip.

Hereinafter, a method for controlling the components of the substrate processing apparatus executed by the controller 70 or the processor 71 will be described in detail.

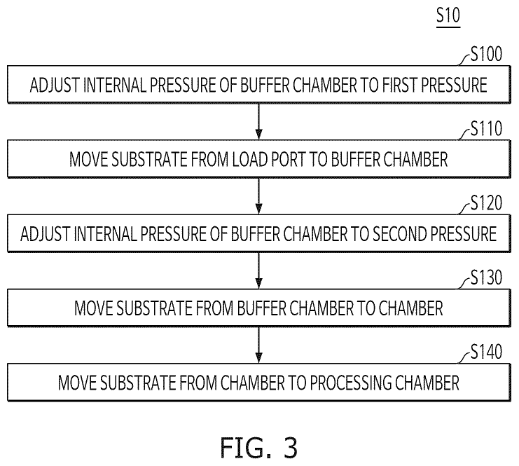

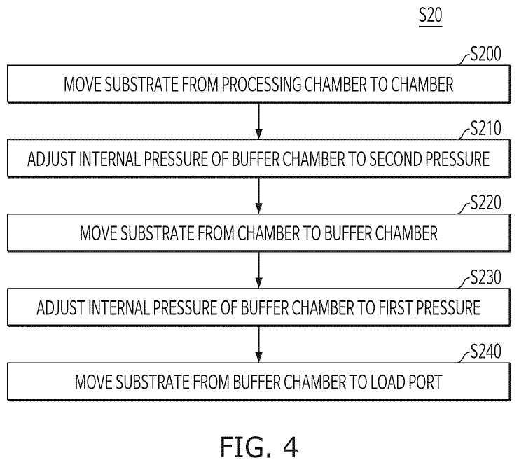

FIGS. 3 and 4 are flowcharts of a transfer process of a substrate in a substrate processing apparatus according to one or more embodiments.

FIG. 3 illustrates an operation of loading a substrate and loading the same into the processing chamber according to one or more embodiments, and FIG. 4 illustrates an operation of unloading the processed substrate according to one or more embodiments. In the operations of FIGS. 3 and 4, the “chamber” may refer to the chamber 20 in which the processing chamber 30 is provided.

Referring to FIG. 3, the substrate transfer method may include an operation of loading the substrate into the processing chamber. An operation S10 of loading the substrate may include first to fifth operations S100 to S140.

The operation S10 of loading the substrate may include the operation S100 of adjusting the internal pressure of the buffer chamber to the first pressure. The load port and the transfer module may be disposed in an area that is under the first pressure. The internal pressure of the buffer chamber may be matched with the first pressure so that the substrate may be received from the load port and the transfer module. By substantially removing the pressure difference between the inside and the outside of the buffer chamber, an inlet of the buffer chamber may be easily opened.

The operation S10 of loading the substrate may include an operation S110 of moving the substrate from the load port to the buffer chamber. The substrate transferred to the load port may be transferred to the buffer chamber. The inlet disposed toward the transfer module of the buffer chamber may be opened, and the substrate may be loaded into the buffer chamber through the inlet.

The operation S10 of loading the substrate may include an operation S120 of adjusting the internal pressure of the buffer chamber to the second pressure. The pressure difference between the buffer chamber and the chamber may be removed so that the substrate loaded into the buffer chamber may be transferred to the chamber. If the second pressure is formed inside the chamber, the internal pressure of the buffer chamber may be adjusted to the second pressure. In one or more embodiments, the pressure sensor may measure the internal pressure of the chamber, and the pressure of the buffer chamber may be adjusted to have the pressure equal to the measured pressure value.

The operation S10 of loading the substrate may include an operation S130 of moving the substrate from the buffer chamber to the chamber. Because the internal pressure of the buffer chamber and the internal pressure of the chamber are substantially the same, the inlet disposed toward the chamber of the buffer chamber may be easily opened. The substrate loaded from the buffer chamber may be transferred in the chamber through the transfer device.

The operation S10 of loading the substrate may include an operation S140 of moving the substrate from the chamber to the processing chamber. The substrate may be loaded into the processing chamber through the transfer device provided inside the chamber. The substrate may be immersed in a processing liquid in the processing chamber.

Referring to FIG. 4, the substrate transfer method may include an operation S20 of unloading the processed substrate. The operation S20 of unloading the substrate may unload the processed substrate to the outside of the substrate processing apparatus.

The operation S20 of unloading the substrate may include an operation S200 of moving the substrate from the processing chamber to the chamber. The processed substrate may be unloaded outside the processing chamber. That is, the substrate may be moved from inside the processing chamber to an inside of the chamber.

The operation S20 of unloading the substrate may include an operation S210 of adjusting the internal pressure of the buffer chamber to the second pressure. The internal pressure of the chamber may be the second pressure. The internal pressure of the buffer chamber may be matched with the second pressure so that the substrate may be received from the chamber. By substantially removing the pressure difference between the inside of the buffer chamber and the inside of the chamber, the inlet of the buffer chamber may be easily opened.

The operation S20 of unloading the substrate may include an operation S220 of moving the substrate from the chamber to the buffer chamber. Because the internal pressure of the buffer chamber and the internal pressure of the chamber are substantially the same, the inlet disposed toward the chamber of the buffer chamber may be easily opened.

The substrate may be moved from the chamber to the buffer chamber through the transfer device.

The operation S20 of unloading the substrate may include an operation S230 of adjusting the internal pressure of the buffer chamber to be equal to the first pressure. The internal pressure of the buffer chamber may be adjusted to the first pressure so that the substrate loaded into the buffer chamber may be transferred to the transfer module and the load port. By substantially removing the pressure difference between the inside and the outside of the buffer chamber, the inlet of the buffer chamber may be easily opened.

The operation S20 of unloading the substrate may include an operation S240 of moving the substrate from the buffer chamber to the load port. The substrate unloaded from the buffer chamber may be moved to the load port by the transfer module. The substrate may be unloaded to the outside of the substrate processing apparatus through the load port.

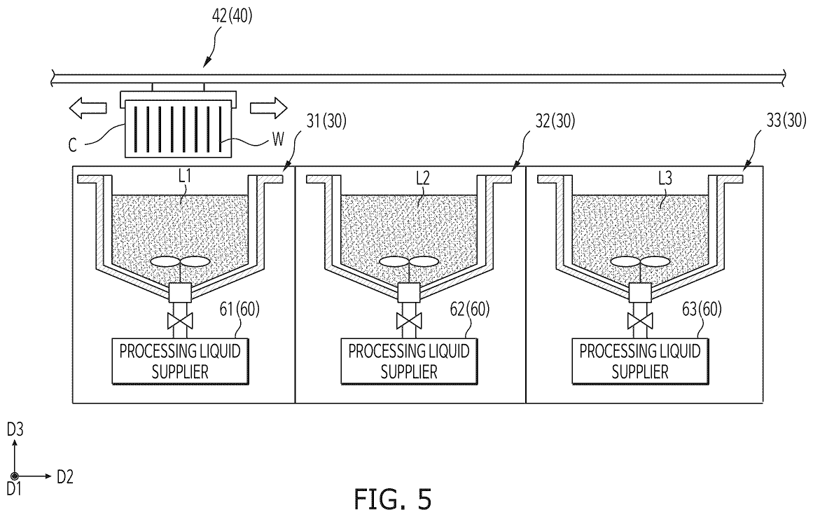

FIG. 5 is a diagram illustrating a partial configuration of the substrate processing apparatus according to one or more embodiments.

Referring to FIG. 5, the substrate W or the container C transferred into the chamber 20 may be loaded into the processing chamber 30 by the second transfer device 42. The second transfer device 42 may move the substrate W or the container C in the second direction D2 or a third direction D3. Specifically, the second transfer device 42 may be movable in the second direction D2 and may move the substrate W or the container C in the third direction D3. The substrate W or the container C may be immersed in a processing liquid contained in the processing chamber 30. For example, the second transfer device 42 may immerse the substrate W or the container C in the processing liquid contained in the first processing chamber 31.

The second transfer device 42 may move the substrate W or the container C processed in the first processing chamber 31 to the second processing chamber 32 or the third processing chamber 33. However, embodiments are not limited to the above, and the substrate W or the container C may be moved to another processing chamber depending on a process recipe, etc.

The substrate processing apparatus according to one or more embodiments may be a batch type processing device. Accordingly, a plurality of substrates W mounted in the container C may be processed at once. The plurality of substrates W may be immersed in the processing liquid while being mounted on the container C. The container C may have a cylindrical shape with an open portion, and may be formed with a space therein for mounting a plurality of substrates W. In addition, the container C accommodating a plurality of substrates W therein may be immersed in the processing liquid supplied to the space of the processing chamber 30. At least one through hole may be formed in the container C, allowing the processing liquid to flow into the container C. That is, a plurality of substrates W mounted on the container C may be immersed in the processing liquid.

The first processing chamber 31 may have an accommodation space for accommodating a first processing liquid L1. The first processing liquid L1 for wet etching may be contained in the first processing chamber 31. The first processing chamber 31 may be connected to a first processing liquid supplier 61. For example, the first processing liquid supplier 61 may be connected to a lower portion of the first processing chamber 31. The first processing liquid supplier 61 may supply the first processing liquid L1 into the first processing chamber 31.

The first processing liquid L1 may be a processing liquid for etching a silicon substrate. For example, the first processing liquid L1 may include tetramethylammonium hydroxide (TMAH), phosphoric acid (H3PO4), hydrofluoric acid (HF), etc. However, embodiments are not limited thereto, and various processing liquids may be supplied according to the target material to be etched.

The second processing chamber 32 may contain a second processing liquid L2 for a rinsing process. The second processing chamber 32 may be connected to a second processing liquid supplier 62. For example, the second processing liquid supplier 62 may be connected to a lower portion of the second processing chamber 32. The second processing liquid supplier 62 may supply the second processing liquid L2 into the second processing chamber 32.

The second processing liquid L2 may rinse away the first processing liquid L1 that may remain on the substrate W or the container C after the processing in the first processing chamber 31 is completed. For example, the second processing liquid L2 may include deionized water, ozone water, CO₂ water, H₂-DIW, etc.

A third processing chamber 33 may contain a third processing liquid L3 for a drying process. The third processing chamber 33 may be connected to a third processing liquid supplier 63. For example, the third processing liquid supplier 63 may be connected to a lower portion of the third processing chamber 33. The third processing liquid supplier 63 may supply the third processing liquid L3 into the third processing chamber 33.

The third processing liquid L3 remaining on the substrate W or the container C after completing the processing in the third processing chamber 33 may be dried. For example, the third processing liquid L3 may include isopropyl alcohol (IPA), tert-butyl alcohol (TBA), etc.

The processing chamber 30 and components around the same will be described in detail.

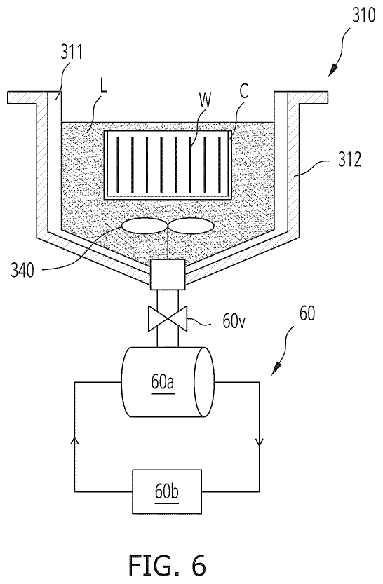

FIG. 6 is a diagram illustrating the processing chamber in an open state according to one or more embodiments. FIG. 7 is a diagram illustrating the processing chamber in a sealed state according to one or more embodiments.

Referring to FIGS. 6 and 7, the processing chamber 30 may include a processing bath 310, a bath cover 320, a sealing member 330, and a rotating member 340.

The processing bath 310 may contain the processing liquid L for processing the substrate W. The processing bath 310 may have a container shape with one open side.

The substrate W or the container C may be loaded in or out through the one side of the processing bath 310. The processing bath 310 may include an inner wall 311 contacting the processing liquid L and an outer wall 312 surrounding the inner wall 311. The inner wall 311 in direct contact with the processing liquid L may include a material having chemical resistance and heat resistance. For example, the inner wall 311 may include Poly Tetra Fluoro Ethylene (PTFE), Per Fluoro Alkoxy (PFA), Flourinated Ethylene Propylene (FEP), Poly VinyliDene Fluoride (PVDF), and quartz, but is not limited thereto. The outer wall 312 may include a material having heat resistance and rigidity to withstand the internal pressure of the processing chamber 30. For example, the outer wall 312 may include stainless steel (SUS), etc., but is not limited thereto.

The processing liquid supplier 60 may be connected to the processing bath 310. The processing liquid supplier 60 may include a storage tank 60a for storing the processing liquid L, a processing liquid heater 60b for heating the processing liquid L, and a processing liquid valve 60v. The processing liquid L may circulate between the storage tank 60a and the processing liquid heater 60b. The processing liquid L may be heated to a certain temperature to exhibit an optimal effect and supplied. The processing liquid L may be discharged from the storage tank 60a, heated through the processing liquid heater 60b, and introduced back into the storage tank 60a. The processing liquid L may be maintained at a predetermined temperature inside the processing liquid supplier 60. The processing liquid supplier 60 may supply the processing liquid L from the storage tank 60a into the processing bath 310.

The controller may control the processing liquid supplier 60 to supply the processing liquid L for processing the substrate W. For example, the controller may control the circulation process between the processing liquid heater 60b, the processing liquid valve 60v or the storage tank 60a and the processing liquid heater 60b so that the processing liquid L has an appropriate temperature to process the substrate W. The controller may control the processing liquid valve 60v so that the processing liquid L is maintained in an appropriate amount in the processing bath 310.

The bath cover 320 may cover the processing bath 310. The bath cover 320 may cover one open side of the processing bath 310. The bath cover 320 may cover one open side of the processing bath 310 after the substrate W or the container C is immersed in the processing liquid L. The bath cover 320 may be coupled to the one open side of the processing bath 310. The bath cover 320 may be coupled to the processing bath 310 to close the inner space of the processing chamber 30.

The sealing member 330 may be disposed between the processing bath 310 and the bath cover 320. The sealing member 330 may be disposed at a coupling portion between the processing bath 310 and the bath cover 320. The sealing member 330 may seal the coupling portion between the processing bath 310 and the bath cover 320. The inner space of the processing chamber 30 may be sealed by the sealing member 330. The sealing member 330 may prevent the gas inside the processing chamber 30 from leaking to the outside. For example, the sealing member 330 may be an O-ring. The sealing member 330 may include synthetic rubber such as nitrile rubber or fluorine rubber, heat resistant plastic, etc.

The bath cover 320 may be coupled to the processing bath 310 in a sliding manner. In one or more embodiments, the bath cover 320 may be coupled to the processing bath 310 by applying pressure. For example, the bath cover 320 may be pressurized hydraulically to be coupled to the processing bath 310 and seal the inside of the processing chamber 30. However, this is only an example, and the bath cover 320 may be coupled to the processing bath 310 in various ways.

The second gas supply device 52 may be connected to the bath cover 320. The second gas supply device 52 may include a second gas supplier 52a for injecting gas and the second pressure adjuster 52b for discharging gas. The second gas supplier 52a may supply gas into the processing chamber 30 to increase the internal pressure of the processing chamber 30. The internal pressure of the processing chamber 30 may be a third pressure higher than the first pressure. The third pressure may be substantially equal to the second pressure of the internal pressure of the chamber 20. The controller may control the second gas supply device 52 so that the internal pressure of the processing chamber 30 becomes the third pressure. That is, the internal pressure of the processing chamber 30 may be substantially equal to the internal pressure of the chamber 20 (see FIG. 1).

The controller may control the second gas supply device 52 to adjust the internal pressure of the processing chamber 30 to the third pressure higher than the first pressure. For example, the controller may inject gas to increase the internal pressure of the processing chamber 30 after the inside of the processing chamber 30 is sealed. If the internal pressure of the processing chamber 30 is higher than the target pressure value, the controller may additionally control the second pressure adjuster 52b to discharge the gas inside the processing chamber 30.

In one or more embodiments, the internal pressure of the processing chamber 30 may be different from the internal pressure of the chamber 20 (see FIG. 1). That is, the third pressure may be higher than the first pressure, and may be different from the second pressure, that is, the internal pressure of the chamber 20 (see FIG. 1).

The rotating member 340 may be disposed in the processing bath 310. The rotating member 340 may cause the processing liquid L to flow. For example, the rotating member 340 may be a stirring blade. The rotating member 340 may generate a water flow in the processing liquid L so that the substrate W is uniformly etched. The rotating member 340 may generate a water flow to form a uniform temperature of the processing liquid L.

A pressure sensor or a temperature sensor may be provided inside the processing chamber 30. The pressure sensor may measure the internal pressure of the processing chamber 30 and transmit the measured pressure data to the controller. The controller may adjust the internal pressure of the processing chamber 30 based on the pressure data. The temperature sensor may measure the internal temperature of the processing chamber 30 and transmit the measured temperature data to the controller. The controller may adjust the internal temperature of the processing chamber 30 based on the temperature data.

According to one or more embodiments, the processing chamber 30 may process the substrate W under a higher pressure than atmospheric pressure. That is, the temperature of the processing liquid L may be maintained higher under a high pressure environment than in an atmospheric pressure environment. As the temperature of the processing liquid L increases, the etch rate may increase, and processing efficiency may be improved.

Hereinafter, the processing chamber described above with reference to FIGS. 6 and 7 will be described according to one or more embodiments. The same components as those described above may be assigned with the same reference numerals, and a detailed description thereof may be omitted.

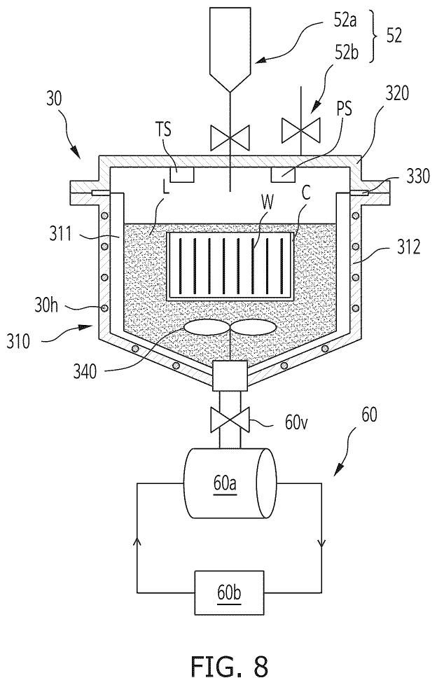

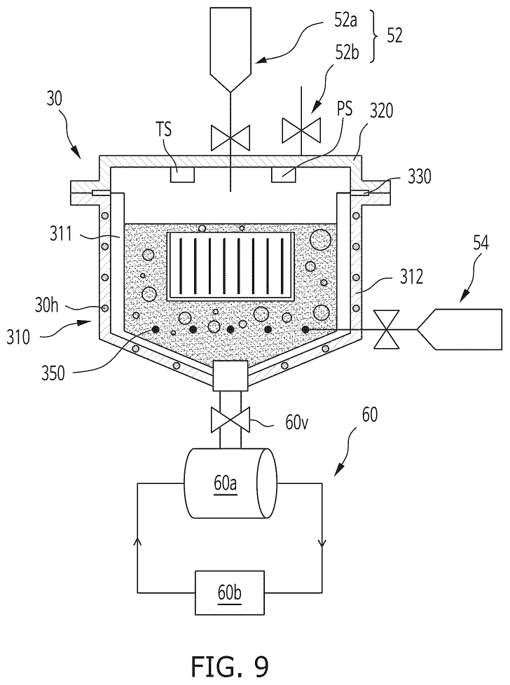

FIGS. 8 and 9 are diagrams illustrating a processing chamber according to one or more embodiments.

Referring to FIG. 8, the processing chamber 30 may include the bath heater 30h. The bath heater 30h may be embedded in the processing bath 310. The bath heater 30h may be embedded in the outer wall 312 of the processing bath 310. The bath heater 30h may adjust the internal temperature or internal pressure of the processing chamber 30.

The pressure sensor PS may measure the internal pressure of the processing chamber 30 and transmit the internal pressure to the controller. The controller may adjust the internal pressure of the processing chamber 30 based on the internal pressure data of the processing chamber 30.

The bath heater 30h may adjust the temperature of the processing liquid L.

After the processing chamber 30 is sealed, the bath heater 30h may heat the processing liquid L to increase the internal pressure of the processing chamber 30 to the third pressure higher than the first pressure.

The bath heater 30h may adjust the temperature of the processing liquid L so that the processing liquid L is maintained at an optimum temperature. For example, the temperature of the processing liquid L may be adjusted to maintain the temperature of the processing liquid L that is supplied after the temperature is increased in the processing liquid supplier 60. In one or more embodiments, if the optimum temperature of the processing liquid L changes as the internal pressure of the processing chamber 30 changes, the bath heater 30h may change the temperature of the processing liquid L in response thereto.

Referring to FIG. 9, the processing chamber 30 may include a bubble generator 350 and a gas supplier 54.

The bubble generator 350 may be formed in the processing bath 310. The bubble generator 350 may be disposed to be lower than the water surface of the processing liquid L. The bubble generator 350 may supply gas to the processing bath 310. The bubble generator 350 may inject gas into the processing bath 310 to form bubbles in the processing liquid L contained in the processing bath 310. The bubbles formed in the processing liquid L may cause the processing liquid L to mix and maintain the temperature of the processing liquid L. The bubbles formed in the processing liquid L may cause the processing liquid L to circulate so that the substrate W is uniformly etched.

The gas supplier 54 may inject gas into the bubble generator 350. The gas supplier 54 may be connected to each processing chamber 30. Some of the plurality of processing chambers 300 may be provided with the bubble generators 350, and some may be provided with the rotating members 340 (see FIG. 8).

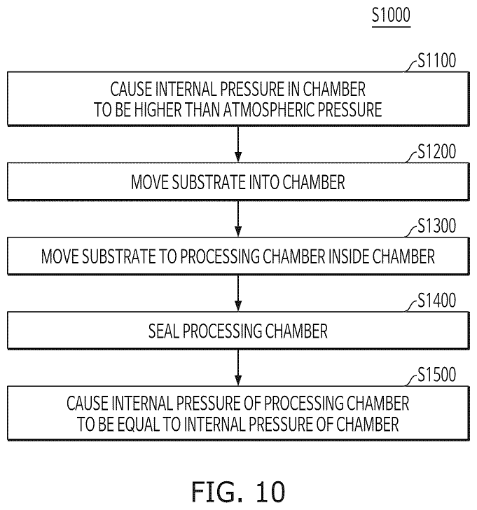

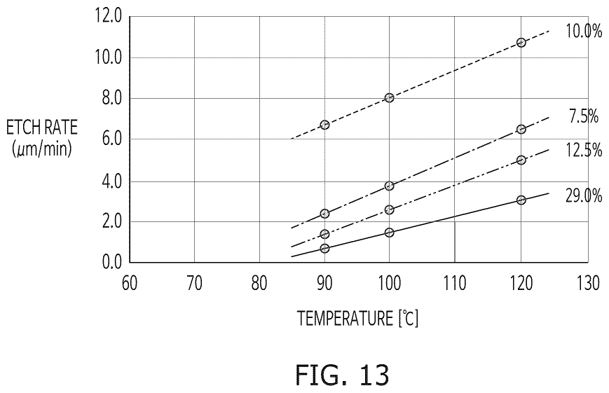

FIG. 10 is a flowchart of a substrate processing method according to one or more embodiments. FIG. 13 is a graph illustrating a relationship between a temperature of processing liquid in a processing chamber and an etch rate according to one or more embodiments. In the operations of FIGS. 10-12, the “chamber” may refer to the chamber 20 in which the processing chamber 30 is provided

Referring to FIG. 10, a substrate processing method S1000 may include first to fifth operations S1100 to S1500.

The substrate processing method S1000 may include loading the substrate through the substrate loader that is under atmospheric pressure. The substrate may be loaded into the substrate processing apparatus for processing. The substrate may be loaded through the load port of the substrate loader. The load port may be disposed under atmospheric pressure.

The substrate processing method S1000 may include adjusting the internal pressure of the buffer chamber to the atmospheric pressure. Before the substrate is moved to the buffer chamber, the internal pressure of the buffer chamber may be adjusted to be equal to the pressure state in which the load port is disposed. That is, a difference between the internal pressure of the buffer chamber and the external pressure of the buffer chamber may be removed.

The substrate processing method S1000 may include moving the substrate to the buffer chamber. The substrate loaded into the load port may be moved to the buffer chamber by the transfer module. A plurality of substrates may be loaded into the load port.

The plurality of substrates may be accommodated in a container and moved. The container accommodating the plurality of substrates may be transferred to the buffer chamber by the transfer module.

The substrate processing method S1000 may include adjusting the internal pressure of the buffer chamber to be equal to the internal pressure of the chamber. The buffer chamber may move the substrate loaded from the load port into the chamber. Since the internal pressure of the chamber is higher than the atmospheric pressure, the buffer chamber may adjust the internal pressure of the buffer chamber before moving the substrate into the chamber. The internal pressure of the buffer chamber may be adjusted to be equal to the internal pressure of the chamber. The third gas supplier may supply gas into the buffer chamber to increase the internal pressure of the buffer chamber.

The substrate processing method S1000 may move the substrate from the buffer chamber to the chamber. The substrate or the container loaded into the buffer chamber may be moved into the chamber by the transfer device.

The substrate processing method S1000 may include an operation S1100 of causing an internal pressure in the chamber to be higher than atmospheric pressure. The internal pressure of the chamber may be formed to be higher than atmospheric pressure. The first gas supplier may supply gas to the chamber to form a pressure higher than atmospheric pressure. That is, the inside of the chamber may be formed in a high pressure state.

The substrate processing method S1000 may include an operation S1200 of moving the substrate into the chamber. The substrate may be moved into the chamber. The substrate may be moved from the substrate loader into the chamber. The transfer module may move the substrate or the container loaded from the load port into the chamber.

The substrate processing method S1000 may include an operation S1300 of moving the substrate to the processing chamber inside the chamber. The substrate or the container loaded into the chamber may be moved to the processing chamber by the transfer device. A processing liquid for processing a substrate may be contained in the processing chamber. The substrate may be immersed in the processing liquid in the processing chamber.

The substrate processing method S1000 may include an operation S1400 of sealing the processing chamber. After the substrate is loaded into the processing chamber, the inside of the processing chamber may be sealed for the substrate processing. The one open side of the processing bath may be covered with the bath cover and thus sealed. The processing chamber may be sealed before gas is injected to form the internal pressure of the processing chamber to a pressure higher than the atmospheric pressure.

The substrate processing method S1000 may include an operation S1500 of causing the internal pressure of the processing chamber to be equal to the internal pressure of the chamber. The second gas supplier may inject gas into the processing chamber after the processing chamber is sealed. The internal pressure of the processing chamber may be formed to be equal to the internal pressure of the chamber. That is, the internal pressure of the processing chamber may be in a high pressure state.

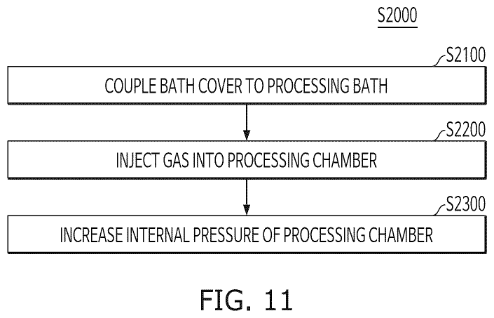

Referring to FIG. 11, a pressure control method S2000 of the processing chamber may include an operation S2100 of coupling the bath cover to the processing bath. The bath cover may be coupled to cover the one open side of the processing bath. The bath cover may be coupled in a sliding manner or a pressing manner. A sealing member may be disposed at a coupling portion between the bath cover and the processing bath. By coupling the bath cover and the processing bath, the inner space of the processing chamber may be sealed.

The method S2000 may include an operation S2200 of injecting gas into the processing chamber. By injecting gas into the sealed processing chamber, the internal pressure of the processing chamber may increase. The second gas supplier may supply gas into the processing chamber. The gas may be a less reactive gas such as nitrogen or argon.

The method S2000 may include an operation S2300 of increasing the internal pressure of the processing chamber. The pressure sensor disposed inside the processing chamber may measure the internal pressure of the processing chamber and transmit the measured result to the controller. Based on the internal pressure data of the processing chamber, the controller may control the gas supplier to supply the gas or control the pressure adjuster to discharging the gas. The controller may compare the internal pressure data of the processing chamber with a target pressure value to control the gas supplier.

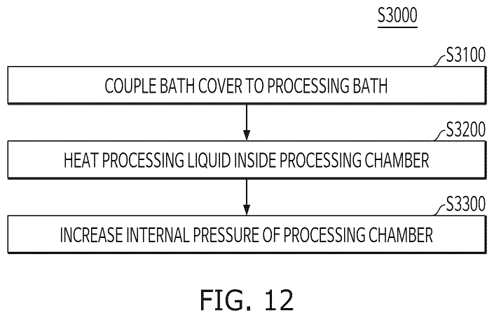

Referring to FIG. 12, a pressure control method S3000 of the processing chamber may include an operation S3100 of coupling the bath cover to the processing bath. The bath cover may be coupled to cover the one open side of the processing bath. The bath cover may be coupled in a sliding manner or a pressing manner. A sealing member may be disposed at a coupling portion between the bath cover and the processing bath. By coupling the bath cover and the processing bath, the inner space of the processing chamber may be sealed.

The method S3000 may include an operation S3200 of heating the processing liquid inside the processing chamber. The bath heater embedded in the processing bath may heat the processing liquid contained in the sealed processing chamber to increase the temperature of the processing liquid.

The controller may control the bath heater in response to receiving an operation input through the input device, or based on pressure data measured from a pressure sensor or temperature data measured from a temperature sensor.

The method S3000 may include the operation S3200 of increasing the internal pressure of the processing chamber. As the temperature of the processing liquid increases, the temperature inside the processing chamber may also increase. Since the pressure is proportional to the temperature, the internal pressure of the processing chamber may increase as the temperature of the processing chamber increases. In addition, as the temperature of the processing liquid increases, the vapor pressure may increase and the internal pressure of the processing chamber may increase. As described above, by heating the processing liquid, the internal pressure of the processing chamber may be increased.

The pressure sensor disposed inside the processing chamber may measure the internal pressure of the processing chamber and transmit the measured result to the controller. The controller may control the gas supplier or the bath heater based on the internal pressure data of the processing chamber. For example, if it is necessary to further increase the internal pressure of the processing chamber, the bath heater may be operated to increase the temperature inside the processing chamber, resulting in an increase in the internal pressure of the processing chamber. The controller may compare the internal pressure data of the processing chamber with a target pressure value to control the gas supplier or the bath heater.

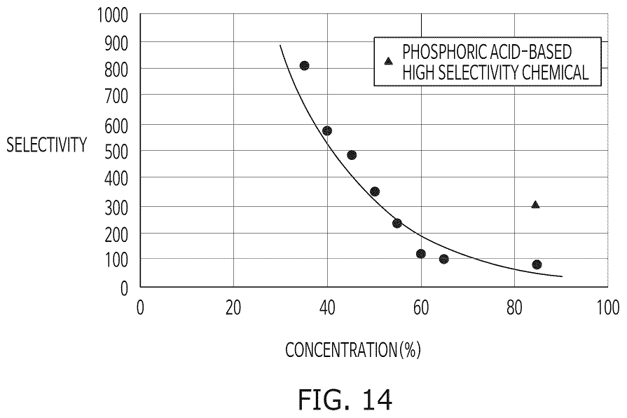

FIG. 13 is a graph illustrating a relationship between a temperature of the processing liquid in the processing chamber and an etch rate according to one or more embodiments. FIG. 14 is a graph illustrating a relationship between a concentration of the processing liquid and selectivity according to one or more embodiments.

The graph of FIG. 13 illustrates an etch rate according to the concentration and temperature of tetramethylammonium hydroxide (TMAH) under a pressure of 4 bar. The etch rate may refer to an etching amount of tetramethylammonium hydroxide (TMAH) per unit time with respect to a silicon (Si) substrate. The temperature and the etch rate of the processing liquid may be proportional to each other regardless of the concentration of the processing liquid. That is, if the temperature of the processing liquid increases, the etch rate increases.

The substrate processing apparatus according to one or more embodiments may process the substrate under a pressure higher than the atmospheric pressure. In a high pressure environment, the processing liquid may be adjusted to a temperature higher than 100° C., which is the boiling point of deionized water at atmospheric pressure. That is, in the high pressure environment, the processing liquid may not be vaporized even if it is heated to 100° C. or higher.

Referring to FIGS. 13, 7.5% concentration of TMAH has an etch rate of 2.4 μm/min at 90° C., but the temperature may be increased to 120° C. in a high pressure environment of approximately 4 bar, and the etch rate may increase by approximately 2.7 times to 6.5μm/min. Even when the processing liquid is heated, the selectivity between silicon (Si) and silicon oxide (SiOx) may be maintained at 3000:1 or more. The processing chamber may process the substrate in a high pressure state such that the etch rate may be improved without degradation of the selectivity.

In addition, etching the silicon (Si) substrate at normal pressure may involve generation of the bubbles on the substrate surface, and the substrate may be unevenly etched to form a hillock on the substrate. Because the processing chamber according to one or more embodiments of the disclosure processes the substrate in the high pressure state, generation of bubbles on the surface of the substrate may be suppressed and formation of the hillock can be prevented. Accordingly, the quality of the substrate processed by the substrate processing apparatus can be improved.

FIG. 14 is a graph illustrating the selectivity between silicon nitride (SiN) and silicon oxide (SiO₂) according to the concentration of phosphoric acid (H₃PO₄) under a pressure of 4 bar. Phosphoric acid-based high selectivity chemical is shown as a reference value.

Referring to FIG. 14, the processing chamber may process the substrate at a high pressure, thus ensuring the high selectivity with a low concentration of phosphoric acid.

If the substrate is processed with phosphoric acid at a concentration of 45% and a temperature of 145° C., the selectivity between silicon nitride and silicon oxide is approximately 470. It may be higher than 300, which is the selectivity of the phosphoric acid-based high-selectivity chemical as a reference value. That is, if the substrate is processed under high pressure, a higher selectivity may be obtained even with a low concentration of phosphoric acid. Therefore, the amount of phosphoric acid used may be reduced, and the viscosity of the processing liquid may be reduced compared to the high concentration phosphoric acid, allowing particles and residual processing liquid to exit more easily. In addition, because the diffusion of the processing liquid may occur more easily, abnormal growth of silicon oxide (SiO₂) may be suppressed.

The tetramethylammonium hydroxide (TMAH) and phosphoric acid (H3PO4) have been described above as an example of the processing liquid, but embodiments are not limited thereto. Obtaining a high etch rate with a low concentration of hydrofluoric acid may be possible even when hydrofluoric acid (HF) is used as the processing liquid to etch silicon nitride (SiN).

According to one or more embodiments, a substrate processing apparatus and a substrate processing method with increased processing efficiency may be provided, which may perform processes at high temperature and high pressure and thus provide the improved etch rate and also ensure the selectivity.

According to one or more embodiments of the disclosure, the substrate processing apparatus and the substrate processing method perform the processes in the high pressure state to prevent defects that may occur when the process is performed under atmospheric pressure and improve the quality of semiconductor devices.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components.

According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

At least one of the devices, units, components, modules, units, or the like represented by a block or an equivalent indication in the above embodiments may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein)

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A substrate processing apparatus, comprising:
a first chamber;
a substrate loader under a first pressure and comprising a load port configured to load a substrate;
a processing chamber inside the first chamber and comprising:
a processing bath in which a processing liquid for processing the substrate is provided, and
a bath cover configured to cover the processing bath;
a processing liquid supplier configured to supply the processing liquid to the processing chamber;
a first gas supply device configured to cause an internal pressure of the first chamber to be at a second pressure higher than the first pressure by supplying gas into the first chamber; and
a second gas supply device configured to cause an internal pressure of the processing chamber to be at a third pressure higher than the first pressure by supplying gas into the processing chamber.

2. The substrate processing apparatus according to claim 1, wherein the substrate loader comprises a buffer chamber configured to receive a substrate moved from the load port and in which an internal pressure is adjustable, and
wherein the substrate processing apparatus further comprises a third gas supply device configured to supply gas to the buffer chamber.

3. The substrate processing apparatus according to claim 2, further comprising a controller configured to control the third gas supply device to adjust the internal pressure of the buffer chamber.

4. The substrate processing apparatus according to claim 3, wherein the controller is further configured to:
adjust the internal pressure of the buffer chamber to the first pressure; and
adjust the internal pressure of the buffer chamber to the second pressure from the first pressure,
wherein the substrate loader is configured to transfer the substrate from the load port to the buffer chamber based on the internal pressure of the buffer chamber being adjusted to the first pressure, and
wherein the substrate loader is configured to transfer the substrate from the buffer chamber to the first chamber based on the internal pressure of the buffer chamber being adjusted to the second pressure from the first pressure.

5. The substrate processing apparatus according to claim 4, wherein the controller is further configured to:
adjust the internal pressure of the buffer chamber to the second pressure; and
adjust the internal pressure of the buffer chamber to the first pressure from the second pressure,
wherein the substrate loader is configured to receive the substrate from the first chamber into the buffer chamber based on the internal pressure of the buffer chamber being adjusted to the second pressure, and
wherein the substrate loader is configured to transfer to the substrate from the buffer chamber to the load port based on the internal pressure of the buffer chamber being adjusted to the first pressure from the second pressure.

6. The substrate processing apparatus according to claim 1, further comprising a controller configured to control the first gas supply device to adjust the internal pressure of the first chamber to the second pressure.

7. The substrate processing apparatus according to claim 6, wherein the controller is configured to further control the second gas supply device to adjust the internal pressure of the processing chamber to the third pressure, and
wherein the second pressure is substantially the same as the third pressure.

8. The substrate processing apparatus according to claim 1, wherein the processing bath comprises an inner wall contacting the processing liquid and an outer wall at least partially surrounding the inner wall, and
wherein a bath heater in the outer wall and configured to control a temperature of the processing liquid.

9. The substrate processing apparatus according to claim 8, further comprising a controller configured to control, based on the internal pressure of the processing chamber, the bath heater to increase the temperature of the processing liquid.

10. The substrate processing apparatus according to claim 1, wherein the processing chamber further comprises a sealing member between the processing bath and the bath cover, the sealing member configured to seal an inside of the processing chamber.

11. The substrate processing apparatus according to claim 1, wherein the processing chamber further comprises a rotating member in the processing bath and configured to cause the processing liquid to flow.

12. The substrate processing apparatus according to claim 1, wherein the processing chamber further comprises a bubble generator configured to form bubbles by injecting gas into the processing liquid.

13. The substrate processing apparatus according to claim 1, wherein the processing liquid supplier comprises a storage tank configured to store the processing liquid, and a processing liquid heater configured to heat the processing liquid, and
wherein the processing liquid circulates between the storage tank and the processing liquid heater.

14. The substrate processing apparatus according to claim 1, wherein the substrate processing apparatus further comprises a transfer device configured to transfer a container accommodating a plurality of substrates.

15. A substrate processing method, comprising:
causing an internal pressure of a first chamber to be higher than an atmospheric pressure by supplying gas through a first gas supply device connected to the first chamber;
moving a substrate into the first chamber;
moving the substrate into a processing chamber in the first chamber, wherein the processing chamber contains a processing liquid for processing the substrate;
sealing the processing chamber by covering the processing chamber with a bath cover; and
causing an internal pressure of the processing chamber to be substantially equal to the internal pressure of the first chamber by supplying gas through a second gas supply device connected to the processing chamber.

16. The substrate processing method according to claim 15, wherein the method comprises:
loading the substrate into a substrate loader, the substrate loader being at the atmospheric pressure;
adjusting an internal pressure of a buffer chamber to the atmospheric pressure;
moving the substrate to the buffer chamber based on the internal pressure of the buffer chamber being adjusted to the atmospheric pressure;
adjusting the internal pressure of the buffer chamber to the internal pressure of the first chamber; and
moving the substrate from the buffer chamber to the first chamber based on the internal pressure of the buffer chamber being adjusted to the internal pressure of the first chamber.

17. The substrate processing method according to claim 16, wherein the moving the substrate to the buffer chamber comprises transferring a container accommodating the substrate to the buffer chamber by a transfer device, and
wherein the moving the substrate from the buffer chamber to the first chamber comprises transferring the container to an inside of the first chamber by the transfer device.

18. The substrate processing method according to claim 15, wherein the method further comprises adjusting a temperature of the processing liquid by controlling a bath heater in the processing chamber.

19. The substrate processing method according to claim 15, wherein the supplying of gas through the second gas supply device comprises controlling the second gas supply device based on the internal pressure of the processing chamber measured by a pressure sensor in the processing chamber.

20. A substrate processing apparatus, comprising:
a first chamber under an internal pressure higher than an atmospheric pressure;
a substrate loader comprising a load port configured to receive a plurality of substrates and a buffer chamber of which an internal pressure is adjustable;
a plurality of processing chambers respectively configured to accommodate the plurality of substrates, each of the plurality of processing chambers containing a processing liquid;
a processing liquid supplier configured to supply the processing liquid to each of the plurality of processing chambers;
a transfer device configured to transfer a batch type container accommodating the plurality of substrates;
a first gas supply device configured to supply gas into the first chamber;
a second gas supply device configured to supply gas into each of the plurality of processing chambers; and
a third gas supply device configured to supply gas to the buffer chamber,
wherein each of the plurality of processing chambers comprises:
a processing bath comprising an inner wall contacting the processing liquid, and an outer wall at least partially surrounding the inner wall, wherein at least one side of the processing bath is open;
a bath cover configured to be coupled to the at least one open side of the processing bath;
a sealing member between the processing bath and the bath cover and configured to seal an inside of a respective processing chamber; and
a bath heater in the outer wall of the processing bath and configured to control a temperature of the processing liquid.
